(19) United States
(12) Patent Application Publication
(10) Pub. No.: US 2006/0290361 A1
(43) Pub. Date: Dec. 28, 2006

(54) A semiconductor integrated circuit tester channel with selective bypass circuitry

(76) Inventors: Travis Ellis, Portland, OR (US); Paul Dana Wohlfarth, Vernonia, OR (US)

Correspondence Address: SMITH-HILL AND BEDELL, P.C., 16100 NW CORNELL ROAD, SUITE 220, BEAVERTON, OR, 97006, US

(21) Appl. No.: 11/166,855

(22) Filed: Jun. 23, 2005

(51) Int. Cl. G01R 27/08

(52) U.S. Cl. 324/713

(57) ABSTRACT

A tester channel including a selective bypass circuit. The selective bypass circuit includes a capacitor, two ferrite beads, and a solid-state relay. The capacitor is connected between a pin electronics circuit and an I/O terminal. One ferrite bead is connected between the pin electronics side of the capacitor and one side of the solid-state relay and the other ferrite bead is connected between the other side of the solid state-relay and the I/O terminal side of the capacitor. The capacitor forms a high frequency path between the pin electronics circuit and the I/O terminal and the first ferrite bead, the solid-state relay, and the second ferrite bead form a low frequency path between the pin electronics circuit and the I/O terminal.

### BACKGROUND OF THE INVENTION

This invention relates to a transistor switch with high frequency blocking.

In the integrated circuit (IC) manufacturing industry, ICs are commonly tested at various stages of the production process to ensure the quality of the ICs being manufactured. This testing is performed with an IC tester.

Referring to FIG. 1, an IC tester 2 for testing a device under test (DUT) 6 typically includes a separate digital tester channel connected at a tester I/O terminal 8 to each terminal 14 of the DUT 6. Each tester channel includes a pin electronics circuit (PEC) 18 for outputting a stimulus signal and receiving a response signal. These test signals are communicated between the PEC 18 and the DUT terminal 14 by a high bandwidth transmission line 26. DUT terminal 14 is also connected via the tester I/O terminal 8 and a transmission line 28 to a precision measurement unit (PMU) 30 for conducting low frequency tests on terminal 14. The IC tester 2 must be able to switch the DUT terminal 14 between its PEC 18 and the PMU 30. A selective bypass circuit 34 and a mechanical relay 38 interrupt transmission line 26. The selective bypass circuit 34 includes a relatively high frequency signal path and a relatively low frequency signal path connected in parallel. Capacitor 50 provides the high frequency path and a solid-state relay 54 provides the low frequency path. Transmission line 28 is interrupted by a solid-state relay 62 acting as an isolation circuit for the PMU 30. The PMU 30 is ohmically connected to the solid-state relay 62. Solid-state relays 54, 62 are phototransistors that switch between open (non-conductive) and closed (conductive) states in response to stimulus from light-emitting diodes (LEDs) 55, 56 respectively.

In operation, the IC tester 2 can be placed in one of four test modes for any given tester channel: high frequency and low frequency modes utilizing the PEC 18, a low frequency mode utilizing both the PEC 18 and the PMU 30, and a low frequency mode utilizing the PMU 30 only.

In the high frequency mode, the IC tester 2 is configured such that the PEC 18 is in high frequency communication with the DUT 6 while the PMU 30 is isolated. To accomplish this, solid-state relay 54 and solid state relay 62 are both placed in the open state while mechanical relay 38 is placed in the closed state. The PEC 18 is thereby AC coupled to the DUT terminal 14 via capacitor 50. AC coupling allows the high frequency components of the test signals to be propagated while the DC components are isolated.

In the low frequency mode utilizing the PEC 18, the IC tester 2 is configured such that the PEC 18 is in DC communication with the DUT 6 while the PMU 30 is isolated. To accomplish this, solid-state relay 54 is placed in the closed state, solid-state relay 62 is placed in the open state and mechanical relay 38 is placed in the closed state. Capacitor 50 presents an open circuit to low frequency components of the signal; therefore the PEC 18 is DC coupled to the DUT terminal 14 via the low frequency path of the selective bypass circuit 34.

In the low frequency mode utilizing the PEC 18 and the PMU 30, the IC tester 2 is configured such that the PEC 18 as well as the PMU 30 are in low frequency communication with the DUT 6. To accomplish this, solid-state relay 54, solid-state relay 62, and mechanical relay 38 are all placed in the closed state. The PEC 18 and the PMU 30 are thereby DC coupled to the DUT terminal 14 via the low frequency path of the selective bypass circuit 34 and the closed state of solid-state relay 62.

In the low frequency mode utilizing the PMU 30 only, solid-state relay 62 is placed in the closed state and mechanical relay 38 is placed in the open state. The PMU 30 is thereby DC coupled to the DUT 6 via the closed state of solid-state relay 62 while the PEC 18 is isolated.

A typical solid-state relay has a relatively high quality (Q) factor resulting in a frequency response that falls off sharply at frequencies above the relay's self-resonant frequency. Above the self-resonant frequency, the impedance of the solid-state relay in the open state falls below a critical threshold allowing the propagation of signal energy. This may result in a parasitic loading of the circuit that includes the solid-state relay. When included in an IC tester channel this parasitic loading decreases the effective bandwidth of the IC tester channel rendering it unsuitable for testing the logic of digital signals having frequency components above the self-resonant frequency of the solid-state relay.

Traditionally, conventional high-speed solid-state relays have been adequate for performing the switching between the digital tester channels and the PMU. Legacy IC signal protocols such as PCI and PCI-X operate at frequencies that have fallen within the operating limits of the solid-state relays. Present and future generations of IC signal protocols such as PCI-E operate at frequencies above the self-resonant frequency of the conventional solid-state relays.

Referring again to FIG. 1, when solid-state relay 54 is in the open state and the DUT 6 and the IC tester 2 are in high-frequency communication, transmission line stub 63 and transmission line stub 64 may cause a discontinuity in the impedance of transmission line 26. This discontinuity can contribute to degradation in the quality of high-frequency components of the test signals traveling over transmission line 26. Similarly, when solid-state relay 62 is in the open state, transmission line stub 65 may also contribute to degradation in the quality of high-frequency components of the test signals traveling over transmission line 26.

It is known that the impedance of a broadband coil inductor increases with frequency. At low frequencies, the coil inductor acts as a short circuit, allowing signals to pass; at higher frequencies the impedance presented by the coil inductor increases, eventually blocking signals from passing.

### SUMMARY OF THE INVENTION

In accordance with a first aspect of the invention there is provided an apparatus for reducing parasitic loading caused by an open transistor switch in a switching circuit, the apparatus comprising a ferrite bead connected to a controlled current terminal of the transistor switch.

In accordance with a second aspect of the invention there is provided a transistor switch having first and second terminals and comprising a transistor having a first current transmission terminal connected to the first terminal of the switch and also having a second current transmission terminal, and a ferrite bead connected between the second current transmission terminal and the second terminal of the switch.

In accordance with a third aspect of the invention there is provided a tester channel for a semiconductor integrated circuit tester, the tester channel having an I/O terminal for connection to a terminal of a device under test and including a pin electronics circuit and a selective bypass circuit connecting the pin electronics circuit to the I/O terminal, the selective bypass circuit comprising a capacitor having a first terminal and a second terminal, the capacitor being connected between the pin electronics circuit and the I/O terminal, a first ferrite bead having a first terminal and a second terminal, the first terminal of the first ferrite bead being connected to the first terminal of the capacitor, a solid-state relay having a first current transmission terminal and a second current transmission terminal, the first current transmission terminal being connected to the second terminal of the first ferrite bead, and a second ferrite bead, having a first terminal and a second terminal, the first terminal of the second ferrite bead being connected to the second current transmission terminal and the second terminal of the second ferrite bead being connected to the second terminal of the capacitor, wherein the capacitor forms a high frequency path between the pin electronics circuit and the I/O terminal and the first ferrite bead, the solid-state relay, and the second ferrite bead form a low frequency path between the pin electronics circuit and the I/O terminal.

In accordance with a fourth aspect of the invention there is provided a parametric measurement channel for a semiconductor integrated circuit tester, the parametric measurement unit channel having an I/O terminal for connection to a terminal of a device under test and including a parametric measurement unit and a isolation circuit connecting the parametric measurement unit to the I/O terminal, the isolation circuit comprising a solid-state relay having a first current transmission terminal and a second current transmission terminal, the solid-state relay being connected to the parametric measurement unit at the first current transmission terminal, and a ferrite bead having a first terminal and a second terminal, the ferrite bead's first terminal being connected to the second current transmission terminal and the ferrite bead's second terminal being connected to the I/O terminal.

### BRIEF DESCRIPTION OF THE DRAWINGS

For a better understanding of the invention, and to show how the same may be carried into effect, reference will now be made, by way of example, to the accompanying drawings, in which:

FIG. 1 is a partial block schematic diagram of a known semiconductor integrated circuit tester, and

FIG. 2 is a partial block schematic diagram of a tester embodying the present invention.

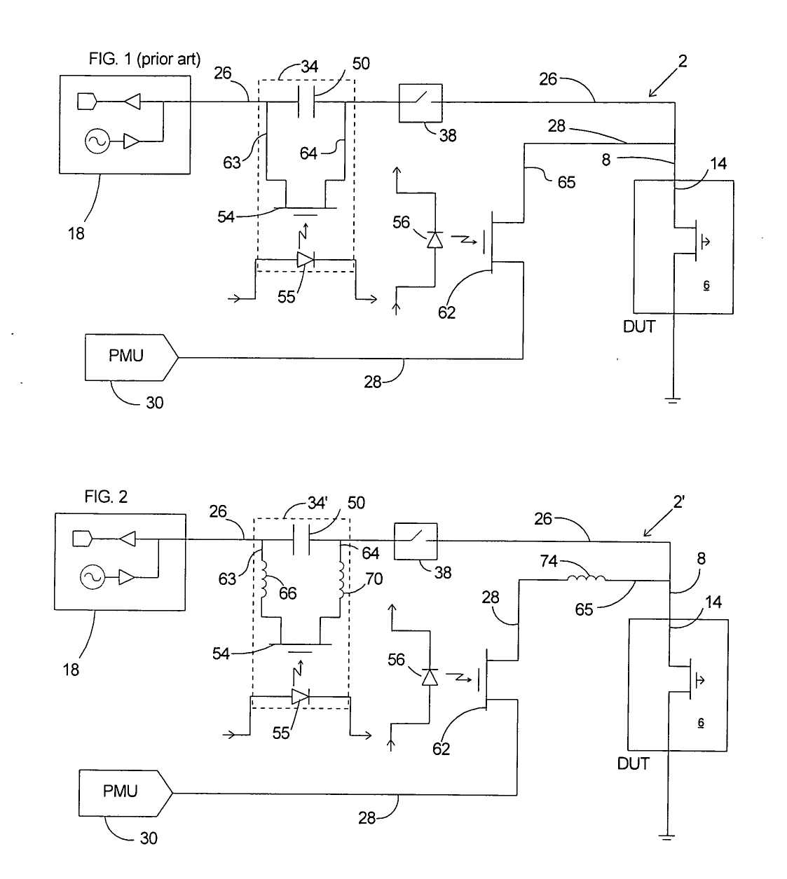

In the several figures of the drawings, like reference symbols represent similar or corresponding elements.

### DETAILED DESCRIPTION

In the selective bypass circuit 34′ of the IC tester 2′ shown in FIG. 2, first and second ferrite beads 66, 70 are connected in series with the solid-state relay 54 to provide the low frequency path. The transmission line 28 includes a third ferrite bead 74 connected between solid-state relay 62 and I/O terminal 8. Suitable ferrite beads are commercially available from Associated Components Technology, Inc. of Garden Grove, Calif. under the designation CBU0603-600-10.

The electrical characteristics of a ferrite bead are generally similar to those of the broadband coil inductor, in that low frequency signals are propagated through the ferrite bead while high frequency energy is dissipated as heat. The ferrite beads 66, 70 connected in series with solid-state relay 54 present a high impedance to the high frequency test signals passing between the tester channel and DUT 6 and block parasitic loading that may be created by the open solid-state relay. Similarly, ferrite bead 74 connected in series with solid-state relay 62 blocks parasitic loading by relay 62 when in the open state. The frequency response of ferrite beads 66, 70 and 74 make them immediately useful in testing the current generation ICs as well as providing headroom for the higher frequency testing that could be required for future generations of ICs. Since ferrite beads that are currently commercially available and have a suitable frequency response for use in the circuit shown in FIG. 2 are small and inexpensive, use of ferrite beads provides a practical means for increasing the usable bandwidth of the high frequency path.

By selectively placing first ferrite bead 66, second ferrite bead 70, and third ferrite bead 74 relatively close to transmission line 26, the ferrite beads will effectively truncate stub 63, stub 64, and stub 65 respectively. The discontinuity in impedance of the transmission line 26 that could otherwise cause a detrimental effect on the quality of high-frequency components of the test signals being transmitted over transmission line 26 is thereby limited.

It will be appreciated that the invention is not restricted to the particular embodiment that has been described, and that variations may be made therein without departing from the scope of the invention as defined in the appended claims and equivalents thereof. For example, it will be appreciated that although the invention has been described in connection with a ferrite bead used in conjunction with a solid-state relay in a selective bypass circuit and a PMU selection circuit of an IC tester the invention may be applied to solid-state switches employed for other purposes. Unless the context indicates otherwise, a reference in a claim to the number of instances of an element, be it a reference to one instance or more than one instance, requires at least the stated number of instances but is not intended to exclude from the scope of the claim a structure having more instances of that element than stated.

1-6. (canceled)

7. A tester channel for a semiconductor integrated circuit tester, the tester channel having an I/O terminal for connection to a terminal of a device under test and including a pin electronics circuit and a selective bypass circuit connecting the pin electronics circuit to the I/O terminal, the selective bypass circuit comprising:
a capacitor having a first terminal and a second terminal, the capacitor being connected between the pin electronics circuit and the I/O terminal,
a first ferrite bead having a first terminal and a second terminal, the first terminal of the first ferrite bead being connected to the first terminal of the capacitor,
a solid-state relay having a first current transmission terminal and a second current transmission terminal, the first current transmission terminal being connected to the second terminal of the first ferrite bead, and
a second ferrite bead, having a first terminal and a second terminal, the first terminal of the second ferrite bead being connected to the second current transmission terminal and the second terminal of the second ferrite bead being connected to the second terminal of the capacitor,
wherein the capacitor forms a high frequency path between the pin electronics circuit and the I/O terminal and the first ferrite bead, the solid-state relay, and the second ferrite bead form a low frequency path between the pin electronics circuit and the I/O terminal.

8. A tester channel according to claim 7, wherein the first and second ferrite beads are placed substantially closer to the terminals of the capacitor than to the terminals of the solid-state relay.

9. A parametric measurement channel for a semiconductor integrated circuit tester, the parametric measurement unit channel having an I/O terminal for connection to a terminal of a device under test and including a parametric measurement unit and a isolation circuit connecting the parametric measurement unit to the I/O terminal, the isolation circuit comprising:
a solid-state relay having a first current transmission terminal and a second current transmission terminal, the solid-state relay being connected to the parametric measurement unit at the first current transmission terminal, and
a ferrite bead having a first terminal and a second terminal, the ferrite bead's first terminal being connected to the second current transmission terminal and the ferrite bead's second terminal being connected to the I/O terminal.

10. A tester channel according to claim 9, wherein the ferrite bead is placed substantially closer to the I/O terminal than to the second current transmission terminal.

11. A tester channel according to claim 9, wherein the ferrite bead's first terminal is ohmically connected to the second current transmission terminal.

12. A tester channel according to claim 9, wherein the ferrite bead and the solid state relay form a low frequency path between the pin electronics and the I/O terminal.

13. A tester channel according to claim 9, wherein the port connects the tester channel to a parametric measurement unit.

14. A tester channel for a semiconductor integrated circuit tester, the tester channel having an I/O terminal for connection to a terminal of a device under test and including a pin electronics circuit, a port for connecting the tester channel to a device external to the tester channel, a first selective bypass circuit for connecting the pin electronics circuit to the I/O terminal, and a second selective bypass circuit for connecting the port to the I/O terminal, the first selective bypass circuit comprising:
a capacitor having a first terminal and a second terminal, the capacitor being connected between the pin electronics circuit and the I/O terminal,
a first ferrite bead having a first terminal and a second terminal, the first terminal of the first ferrite bead being connected to the first terminal of the capacitor,
a first solid-state relay having a first current transmission terminal and a second current transmission terminal, the first current transmission terminal being connected to the second terminal of the first ferrite bead, and
a second ferrite bead, having a first terminal and a second terminal, the first terminal of the second ferrite bead being connected to the second current transmission terminal and the second terminal of the second ferrite bead being connected to the second terminal of the capacitor,
and the second selective bypass circuit comprises:
a second solid-state relay having a first current transmission terminal and a second current transmission terminal, the first current transmission terminal of the second solid-state relay being connected to the port, and
a third ferrite bead having a first terminal and a second terminal, the third ferrite bead's first terminal being connected to the second solid-state relay's second current transmission terminal and the ferrite bead's second terminal being connected to the I/O terminal, and
wherein the capacitor forms a high frequency path between the pin electronics circuit and the I/O terminal, the first ferrite bead, the first solid-state relay, the second ferrite bead form a low frequency path between the pin electronics circuit and the I/O terminal, and the second solid-state relay and the third ferrite bead form a low frequency path between the port and the I/O terminal.

15. A tester channel according to claim 14, wherein the first terminal of the first ferrite bead is ohmically connected to the first terminal of the capacitor, the first current transmission terminal is ohmically connected to the second terminal of the first ferrite bead, the first terminal of the second ferrite bead is ohmically connected to the second current transmission terminal, and the second terminal of the second ferrite bead is ohmically connected to the second terminal of the capacitor.

16. A tester channel according to claim 14, wherein the third ferrite bead's first terminal is ohmically connected to the second solid-state relay's second current transmission terminal.

17. A tester channel according to claim 14, wherein the port connects the tester channel to a parametric measurement unit.
